(19) United States
(12) Patent Application Publication
(10) Pub. No.: US 2024/0222467 A1
(43) Pub. Date: Jul. 4, 2024

(54) METHOD OF MANUFACTURING INTEGRATED CIRCUIT DEVICE

(71) Applicant: SAMSUNG ELECTRONICS CO., LTD., Suwon-si (KR)

(72) Inventors: Jieun YUN, Suwon-si (KR); Sunhye HWANG, Suwon-si (KR); Gyeom KIM, Suwon-si (KR); Ji Young PARK, Suwon-si (KR); Sangmoon LEE, Suwon-si (KR)

(21) Appl. No.: 18/243,251

(22) Filed: Sep. 7, 2023

(30) Foreign Application Priority Data
Dec. 27, 2022 (KR) 10-2022-0186010

(51) Int. Cl. H01L 29/66; H01L 21/02; H01L 29/06; H01L 29/08; H01L 29/161; H01L 29/423; H01L 29/775

(52) U.S. Cl. CPC H01L 29/66439; H01L 21/02532; H01L 21/02579; H01L 21/0262; H01L 29/0673; H01L 29/0847; H01L 29/161; H01L 29/42392; H01L 29/66545; H01L 29/66553; H01L 29/775

(57) ABSTRACT

A method of manufacturing an integrated circuit device, the method including forming a structure on a substrate, a semiconductor film and an insulating film being exposed in the structure, and selectively forming a silicon germanium layer only on the semiconductor film by using a process gas, the process gas including a disilane compound having at least two chlorine atoms, a germanium element-containing gas, and hydrogen gas.

### CROSS-REFERENCE TO RELATED APPLICATION

Korean Patent Application No. 10-2022-0186010, filed on Dec. 27, 2022, in the Korean Intellectual Property Office, is incorporated by reference herein in its entirety.

### BACKGROUND

### 1. Field

A method of manufacturing an integrated circuit device is disclosed.

### 2. Description of the Related Art

In recent years, due to the development of electronics technology, the downscaling of semiconductor devices has rapidly progressed, and thus, patterns included in electronic devices have been miniaturized.

### SUMMARY

Embodiments are directed to a method of manufacturing an integrated circuit device, the method including forming a structure on a substrate, a semiconductor film and an insulating film being exposed in the structure, and selectively forming a silicon germanium layer only on the semiconductor film by using a process gas, the process gas including a disilane compound having at least two chlorine atoms, a germanium element-containing gas, and hydrogen gas.

Embodiments are directed to a method of manufacturing an integrated circuit device, the method including forming a fin-type active region on a substrate, the fin-type active region extending long in a first lateral direction, forming a plurality of dummy gate structures on the fin-type active region, the plurality of dummy gate structures extending long in a second lateral direction, and each dummy gate structure including a dummy gate layer and an insulating capping layer covering the dummy gate layer, wherein the second lateral direction intersects with the first lateral direction, forming a plurality of insulating spacers covering both sidewalls of each of the plurality of dummy gate structures, etching a portion of the fin-type active region by using the plurality of dummy gate structures and the plurality of insulating spacers as an etch mask to form a recess in the fin-type active region, and selectively forming a source/drain region on a surface of the fin-type active region, which is exposed at the recess, by using a process gas, the process gas including a disilane compound having at least two chlorine atoms, a germanium element-containing gas, and hydrogen gas.

Embodiments are directed to a method of manufacturing an integrated circuit device, the method including forming a fin-type active region on a substrate, the fin-type active region extending long in a first lateral direction, forming a plurality of dummy gate structures on the fin-type active region, the plurality of dummy gate structures extending long in a second lateral direction, and each dummy gate structure including a dummy gate layer and an insulating capping layer covering the dummy gate layer, wherein the second lateral direction intersects with the first lateral direction, forming a plurality of insulating spacers covering both sidewalls of each of the plurality of dummy gate structures, forming a nanosheet stack apart from a fin top surface of the fin-type active region, the nanosheet stack facing the fin top surface of the fin-type active region in a vertical direction, and the nanosheet stack including a plurality of nanosheets that are at different vertical distances from the fin top surface of the fin-type active region, etching a portion of the fin-type active region by using the plurality of dummy gate structures and the plurality of insulating spacers as an etch mask to form a recess in the fin-type active region, and epitaxially growing a silicon germanium layer from a surface of the fin-type active region and a surface of each of the plurality of nanosheets at a temperature of about 350° C. to about 450° C. by using a process gas to form a source/drain region, the process gas including a disilane compound having at least two chlorine atoms, a germanium element-containing gas, and hydrogen gas.

### BRIEF DESCRIPTION OF THE DRAWINGS

Features will become apparent to those of skill in the art by describing in detail exemplary embodiments with reference to the attached drawings in which:

FIG. 1 is a flowchart showing steps in a method of manufacturing an integrated circuit device according to an example embodiment.

FIGS. 2A to 2C are cross-sectional views of stages in a method for manufacturing an integrated circuit device according to example embodiments.

FIG. 3 is a diagram showing an example embodiment of a germanium element-containing gas.

FIG. 4 is a plan layout diagram showing an integrated circuit device according to an example embodiment.

FIGS. 5A to 5L are cross-sectional views of stages in a method for manufacturing an integrated circuit device according to example embodiments.

### DETAILED DESCRIPTION

Hereinafter, embodiments will be described in detail with reference to the accompanying drawings. The same reference numerals are used to denote the same elements in the drawings, and repeated descriptions thereof are omitted.

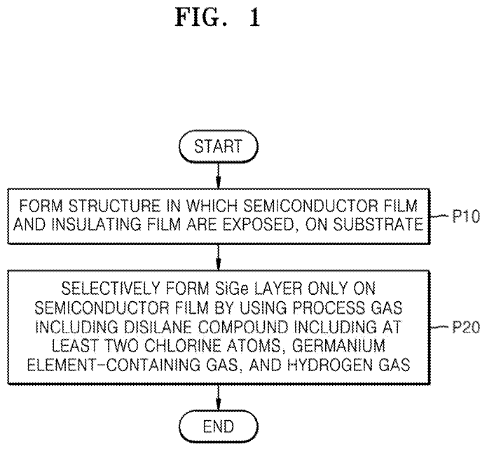

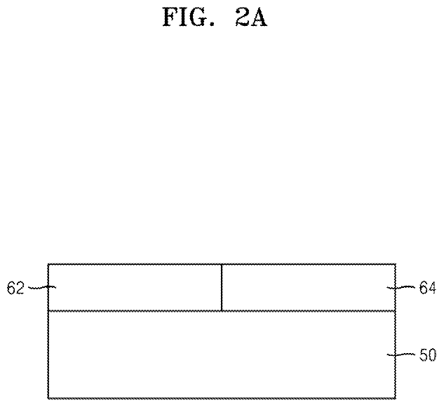

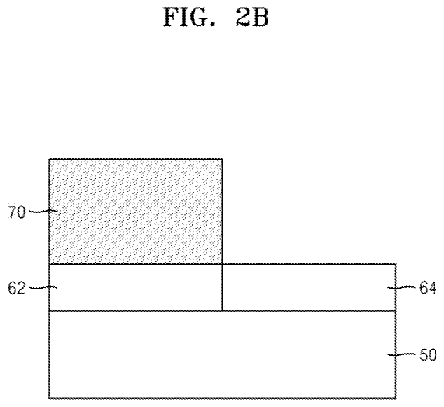

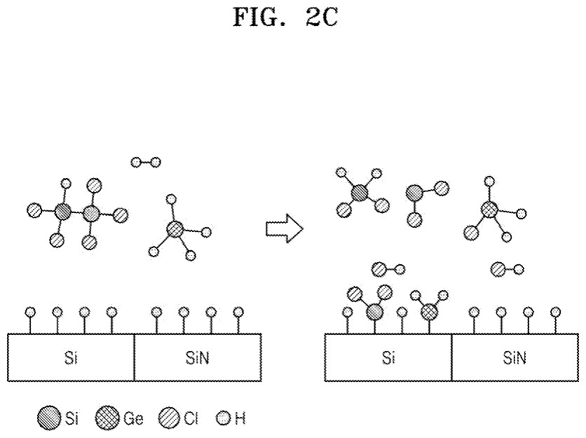

FIG. 1 is a flowchart showing steps in a method of manufacturing an integrated circuit device according to an example embodiment. FIGS. 2A to 2C are cross-sectional views of stages in a method for manufacturing an integrated circuit device according to example embodiments.

Referring to FIGS. 1 and 2A, in process P10, a structure in which a semiconductor film 62 and an insulating film 64 are exposed may be formed on a substrate 50. The substrate 50 may include a semiconductor substrate. The substrate 50 may include the semiconductor substrate and a lower structure on the semiconductor substrate. The lower structure may include various conductive regions (e.g., wiring layers, contact plugs, and transistors) and insulating patterns configured to insulate the conductive regions from each other.

In example embodiments, the semiconductor film 62 may include a silicon (Si) film, or a silicon germanium (SiGe) layer. The insulating film 64 may include a nitrogen (N)-containing insulating film. In an implementation, the insulating film 64 may include silicon nitride (SiN), silicon oxynitride (SiON), silicon oxycarbonitride (SiOCN), silicon boron nitride (SiBN), or silicon carbon nitride (SiCN). As used herein, each of the terms “SiN,” “SiON,” “SiOCN,” “SiBN,” and “SiCN” refers to a material including elements included therein, without referring to a chemical formula representing a stoichiometric relationship. As used herein, the term “or” is not an exclusive term, e.g., “A or B” would include A, B, or A and B.

Referring to FIGS. 1 and 2B, in process P20, a SiGe layer 70 may be selectively formed only on the semiconductor film 62, from among the semiconductor film 62 and the insulating film 64, by using a process gas including a disilane compound including at least two chlorine (Cl) atoms, a germanium (Ge) element-containing gas, and hydrogen (H₂) gas.

In embodiments, the disilane compound included in the process gas may include dichlorodisilane, trichlorodisilane, tetrachlorodisilane, pentachlorodisilane, or hexachlorodisilane. The Ge element-containing gas included in the process gas may include germane (GeH₄) or digermane (Ge₂H₆). To form the SiGe layer 70, an additional Cl element-containing gas (e.g., hydrogen chloride (HCl)) may not be used in addition to the disilane compound.

In embodiments, the process gas may further include at least one dopant precursor. The dopant precursor may include a boron (B) precursor, a gallium (Ga) precursor, an indium (In) precursor, or an aluminum (Al) precursor.

The SiGe layer 70 may be formed by using a low-pressure chemical vapor deposition (LPCVD) process, a selective epitaxial growth (SEG) process, or a cyclic deposition and etching (CDE) process. The formation of the SiGe layer 70 may be performed at a temperature of about 300° C. to about 500° C., e.g., about 350° C. to about 450° C.

In embodiments, the formation of the SiGe layer 70 may include simultaneously supplying the disilane compound, the Ge element-containing gas, and the hydrogen (H₂) gas onto the substrate 50. In an implementation, the SiGe layer 70 may be formed by using a process gas including pentachlorodisilane, germane (GeH₄), hydrogen (H₂) gas, and a boron dopant precursor. Of the process gas, at least pentachlorodisilane, germane (GeH₄), and hydrogen (H₂) gas may be simultaneously supplied onto the substrate 50.

As the development of the semiconductor industry requires the development of IC devices having various structures and various characteristics, the demand for low-temperature processes increases. There may be cases in which a selective deposition technique is desirable to manufacture an IC device. For instance, it may be desirable to control a desired material to be deposited only on a surface of a silicon film by using an epitaxial growth process, but not to be deposited on a surface of an insulating film (e.g., a silicon nitride film or a silicon oxide film). A technique for depositing a desired material only on a specific surface in a structure in which films including at least two different materials are exposed may be referred to as a selective growth process or a deposition selectivity. The deposition selectivity may be determined by a nucleation rate on any one surface or by an etch rate of a film grown on any one surface. In a deposition process using an epitaxial grown process, even when an epitaxial film is formed on a silicon surface, an amorphous film may be formed on a silicon nitride surface or an oxide surface. The amorphous film deposited on the silicon nitride surface or the oxide surface may have a higher etch rate than the epitaxial film. Accordingly, by adding an etch gas during the deposition process, the deposition process may be accompanied by the etching of the amorphous film deposited on the silicon nitride surface or the oxide surface, and thus, a deposition selectivity in the deposition process may be ensured.

A silicon-containing thin film may be formed on a substrate by using a silane compound as a silicon source. The silicon-containing thin film may be epitaxially or non-epitaxially deposited by using a CVD process. The silicon-containing thin film may be selectively grown by using a chlorosilane compound, such as monochlorosilane, dichlorosilane, and trichlorosilane.

To increase a growth selectivity of the silicon-containing thin film, an etch gas (e.g., HCl) may be additionally used to remove nuclei generated on surfaces other than the silicon surface. However, the chlorosilane compound may have a sharply reduced deposition rate due to a low reactivity thereof at a relatively low temperature, thus resulting in productivity degradation. Furthermore, an etch rate of HCl gas, which is an etch gas, may be reduced at a relatively low temperature, and thus, a deposition selectivity may be degraded in a process requiring selective deposition. Accordingly, it is desirable to develop new materials and deposition processes, which enable selective deposition at a relatively low temperature at a high deposition rate.

Embodiments may provide a method of selectively forming a silicon-containing layer (e.g., a SiGe layer) only on a semiconductor film by using a disilane compound including at least two Cl atoms. The silicon-containing layer may be deposited at a relatively low temperature of about 300° C. to about 500° C., e.g., about 350° C. to about 450° C., a deposition rate of the silicon-containing layer may be relatively high, and a deposition selectivity may be ensured without an additional etch gas (e.g., HCl).

In addition, a deposition selectivity may be further increased by using a Ge element-containing gas (e.g., germane (GeH₄) or digermane (Ge₂H₆)) together with the disilane compound including at least two Cl atoms.

FIG. 2C illustrates a deposition mechanism when a disilane compound including at least two Cl atoms, a Ge element-containing gas, and hydrogen (H₂) gas are supplied onto a surface of each of a silicon (Si) film and a silicon nitride (SiN) film.

FIG. 2C illustrates an example mechanism by which an SEG process is enabled without using an additional etch gas (e.g., HCl) when a CVD process is performed by using pentachlorodisilane (PCDS) as the disilane compound and using germane (GeH₄) as the Ge element-containing during the formation of the SiGe layer 70 according to the method described with reference to FIGS. 1, 2A, and 2B

Referring to FIG. 2C, PCDS may be adsorbed in the form of SiCl₂ on the surface of the Si film as a Si—Si bond is dissociated. GeH₄ may be adsorbed in the form of GeH₂ on the surface of the Si film or ligand exchange may occur in the form of GeHₓCl_{y} (here, x is an integer of 1 to 3 and y is an integer of 1 to 4). H₂ gas may contribute to hydrogen termination on a surface to be deposited or may combine with Cl groups to generate HCl. SiCl₂, which is produced by dissociation of PCDS, may be more difficult to be adsorbed on the surface of the SiN film than on the surface of the Si film due to a difference in surface adsorption energy between the Si film and the SiN film.

More specifically, in the CVD process, PCDS may be grown by decomposed species after vapor-phase decomposition and by a surface reaction of molecules. However, when comparing energy required for a growth reaction by the decomposed species with energy required for a growth reaction by the surface reaction of the molecules, energy required for the vapor-phase decomposition of PCDS may be about 1.990 eV, while surface adsorption energy of PCDS may be about 3.263 eV. In a typical high-temperature deposition process (e.g., a process performed at a temperature of about 500° C. or higher), vapor-phase decomposition and surface adsorption may occur simultaneously. However, in a relatively low-temperature process (e.g., a process performed at a temperature of about 450° C. or lower), it may be difficult to achieve deposition by a surface requiring relatively high energy, while deposition may be achieved by a vapor-phase decomposition reaction requiring relatively low energy. In an implementation, in a structure of PCDS, the Si—Si bond may be weaker than a Si—H bond and a Si—Cl bond in terms of bond dissociation energy between atoms. As a result, the Si—Si bond may be broken down first. Accordingly, the vapor-phase decomposition of PCDS may proceed in a path in which the Si—Si bond is broken down first. A path of a vapor-phase decomposition reaction of PCDS may be represented by Reaction Scheme 1 and Reaction Scheme 2:

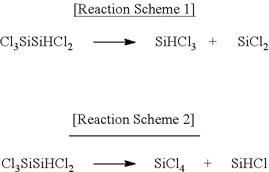

The vapor-phase decomposition reaction of PCDS may be expected to proceed in a path having a relatively low energy value, from among paths of Reaction Scheme 1 and Reaction Scheme 2. As a result of the comparison of corresponding energy values in the above-described point of view, the vapor-phase decomposition reaction of PCDS may proceed in the path of Reaction Scheme 1, SiCl₂ may be adsorbed on and react with the surface, SiHCl₃ may be decomposed again into SiCl₂+HCl, and the generated SiCl₂ may also be adsorbed on and react with the surface.

In addition, thermal decomposition energy of PCDS may be lower than thermal decomposition energies of chloromonosilane (SiHₙCl₄₋ₙ, n is an integer of 1 to 3) compounds. Accordingly, the method may be advantageous at a relatively low temperature. In an implementation, thermal decomposition activation energy of hexachlorodisilane (HCDS) (Si₂Cl₆) may be about 49 kcal/mol, and a thermal decomposition temperature of HCDS may be about 327° C. Thermal decomposition activation energy of PCDS may be about 45.9 kcal/mol, which is slightly lower than thermal decomposition activation energy of HCDS, and a decomposition reaction of PCDS may be expected to proceed at a lower temperature than a decomposition reaction of HCDS.

In addition, differential scanning calorimetry (DSC) analysis results showed that a decomposition temperature of PCDS is about 269° C. From the analysis results, when PCDS is used, the deposition of a silicon-containing layer may be implemented at a relatively low temperature of about 300° C. to about 500° C., e.g., about 350° C. to about 450° ° C.

Unlike the case of PCDS, in the case of dichlorosilane (DCS), which is a comparative example, energy required for vapor-phase deposition may be about 3.369 eV and a decomposition reaction may proceed at a temperature of about 600° C. or higher under standard conditions. Thus, it may be expected that DCS is difficult to use as a material to be deposited at a relatively low temperature. In an implementation, because thermal decomposition energy of a chlorodisilane compound is lower than thermal decomposition energy of a chlorosilane compound, the chlorodisilane compound may decompose more easily than the chlorosilane compound at a relatively low temperature. Accordingly, a reaction rate of the chlorodisilane compound may be higher than a reaction rate of the chlorosilane compound at a relatively low temperature.

When a thin film is deposited by using the chlorosilane compounds, reactive species may be in the form of SiCl₂, SiHCl, and SiH₂. In contrast, a decomposition reaction of PCDS may proceed in the form of SiCl₂. When both a surface of the semiconductor film (e.g., a Si film) and a surface of the insulating film (e.g., a silicon nitride film) are exposed, a selective deposition process by which a SiGe layer is selectively formed only on the surface of the semiconductor film may be performed. Thus, activation energies (hereinafter, adsorption energies) required for surface adsorption of reactive species (e.g., SiCl₂, SiClH, and SiH₂) on the surface of the Si film and the surface of the SiN film were calculated and compared. The calculation and comparison results are shown in Table 1.

TABLE 1

Adsorption energy [eV]

| | Si film | SiN film |
|---|---|---|
| SiCl₂ | 1.294 | 2.291 |
| SiHCl | 0.996 | 1.962 |
| SiH₂ | — | 0.503 |

In Table 1, SiCl₂, which is a representative reactive species of PCDS, requires a relatively high adsorption energy of about 2.29 eV on the SiN surface. This may indicate that a nucleation rate of SiCl₂ is lower on the SiN surface than on the Si surface, and the difference between and the nucleation rate of SiCl₂ on the SiN surface and a nucleation rate of SiCl₂ on the SiN surface is large. In addition, the difference in the nucleation rate may increase as temperature decreases. Accordingly, it can be expected that a deposition selectivity may be ensured only by using the difference in nucleation rate without injecting an additional etch gas at a relatively low temperature of about 300° C. to about 500° C., e.g., about 350° ° C. to about 450° C.

Based on simulation calculation values of Table 1, a CVD process was performed on the surface of each of the Si film and the SiN film by using PCDS, GeH₄, and H₂ gas at a temperature of about 475° C. As a result, the SiGe layer was selectively deposited only on the surface of the Si film, from among the Si film and the SiN film.

Furthermore, it was evaluated whether a selectivity is improved according to a flow rate of each of PCDS and GeH₄. As a result, when PCDS and GeH₄ were simultaneously supplied onto a substrate, a deposition selectivity improved as the flow rate of GeH₄ increased. Therefore, the Ge element-containing gas may help improve a deposition selectivity.

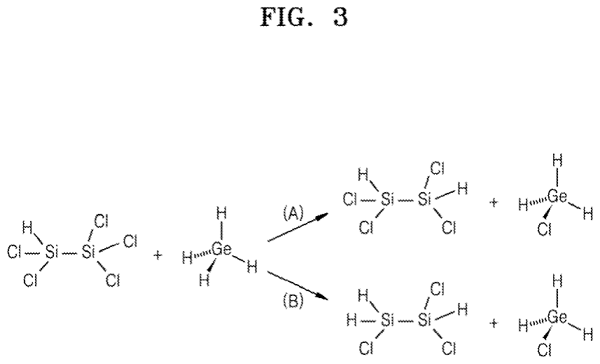

FIG. 3 is a diagram showing an example embodiment of a germanium element-containing gas. Referring to FIG. 3, in a CVD process, GeH₄ may be decomposed into GeH₂+H₂, and may be adsorbed in the form of GeH₂ on a surface to be deposited. As a CVD process temperature decreases, GeH₄ decomposition efficiency may be reduced, and undecomposed GeH₄ may react with PCDS to cause ligand exchange between H and Cl. As a result, as shown in a reaction path (A) and a reaction path (B) of FIG. 3, a structure of GeHₓCl₄₋ₓ (x is an integer of 0 to 3) may be obtained from GeH₄. In an implementation, at room temperature, ligand exchange energy in the reaction path (A) of FIG. 3 may be about 0.078 eV, and ligand exchange energy in the reaction path (B) of FIG. 3 may be about 0.065 eV. Thus, reactions according to the reaction paths (A) and (B) may be expected to easily occur even at room temperature. GeCl₄ may be generated by sequential ligand exchange of GeH₄. The generated GeCl₄ may serve as an etch gas at a relatively low temperature.

As a comparative example, at a relatively low temperature (e.g., about 450° C.), the etching efficiency of chlorine (Cl₂) gas sharply dropped, while the etching efficiency of GeCl₄ was higher than that of the chlorine gas. Accordingly, GeCl₄ may be generated by simultaneously supplying PCDS and GeH₄ onto a substrate at a relatively low temperature, and an amorphous SiGe layer deposited on a surface of a SiN film may be etched by using the generated GeCl₄. Thus, a deposition selectivity may be further improved.

When a SiGe layer is formed, as a ratio of a flow rate of a Ge element-containing gas to a flow rate of a disilane compound increases, a deposition selectivity by which the SiGe layer is selectively formed only on a semiconductor film, from among an insulating film and the semiconductor film, may be further improved. In embodiments, in a CVD process for forming the SiGe layer by simultaneously supplying PCDS and GeH₄, a deposition selectivity may be maximized as a flow rate of GeH₄ increases under a condition that a flow rate of PCDS is constant. In an implementation, when the SiGe layer is formed by performing the CVD process by simultaneously supplying PCDS, GeH₄, and H₂ gas onto a substrate at a temperature of about 350° C. to about 450° C., a ratio of a flow rate of GeH₄ to a flow rate of PCDS may be determined such that a ratio of a content of germanium atoms to a content of silicon atoms in a process gas is at least about 30%. In an implementation, with respect to the same deposition time, when the ratio of the content of germanium atoms to the content of silicon atoms in the process gas is at least about 30%, a deposition selectivity of the SiGe layer may be further improved as compared to the case in which the ratio of the content of germanium atoms to the content of silicon atoms in the process gas is at least about 20%.

A silicon-containing layer may be selectively deposited only on the semiconductor film by using the disilane compound including at least two Cl atoms and the Ge element-containing gas and may be deposited at a relatively low temperature of about 450° C. or lower. Thus, the method may be advantageously applied to a process of manufacturing various types of IC devices having various structures and characteristics, which require low-temperature processes. A higher deposition rate may be provided as compared to the case of using a monosilane compound, such as monochlorosilane (MCS) and dichlorosilane (DCS), and a desired level of a deposition selectivity may be easily ensured without using an additional etch gas. Furthermore, an improved deposition selectivity may be ensured by additionally using the Ge element-containing gas, such as germane (GeH₄) and digermane (Ge₂H₆).

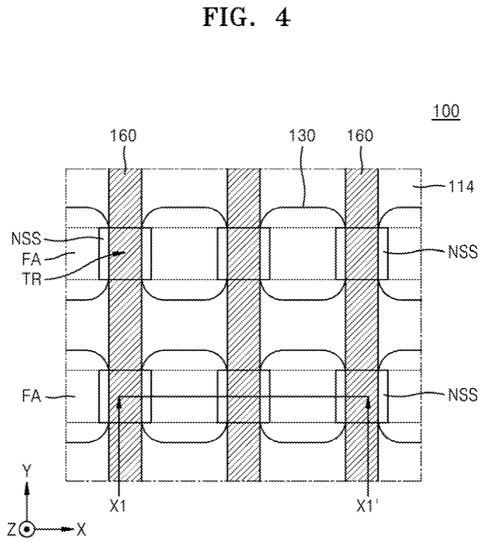

FIG. 4 is a plan layout diagram showing an integrated circuit device according to an example embodiment. The IC device 100 including a field-effect transistor (FET) TR having a gate-all-around structure including an active region of a nanowire or nanosheet type and a gate surrounding the active region is described with reference to FIG. 4.

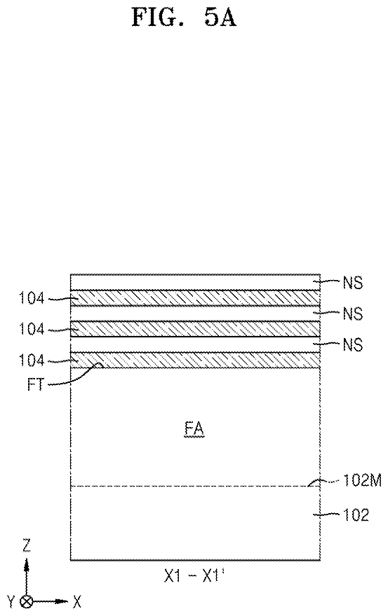

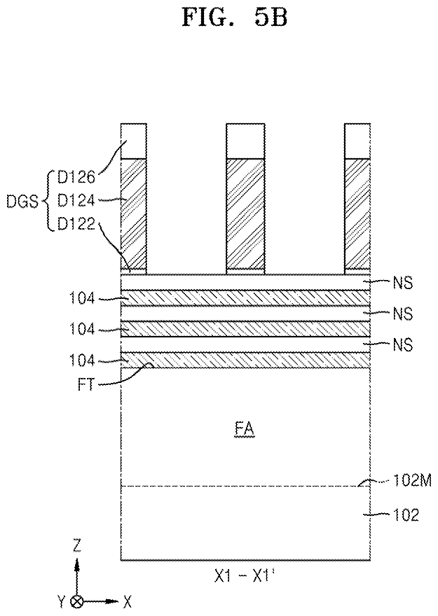

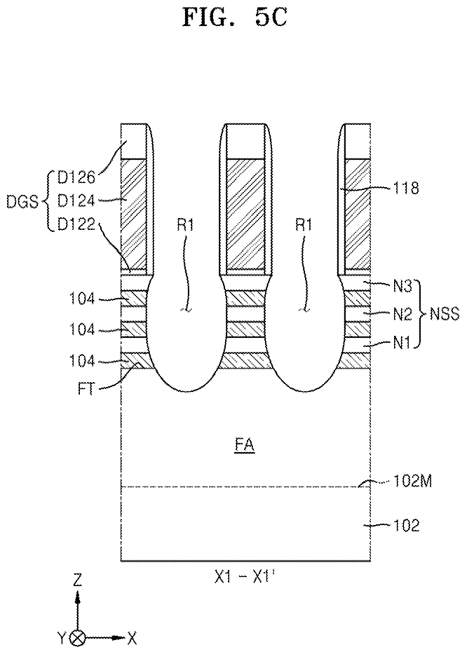

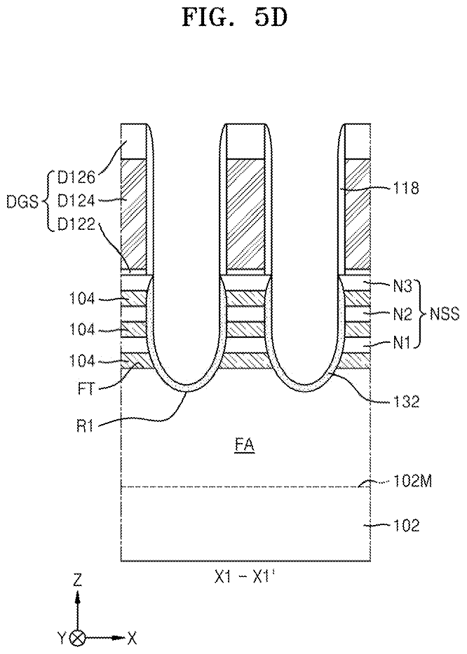

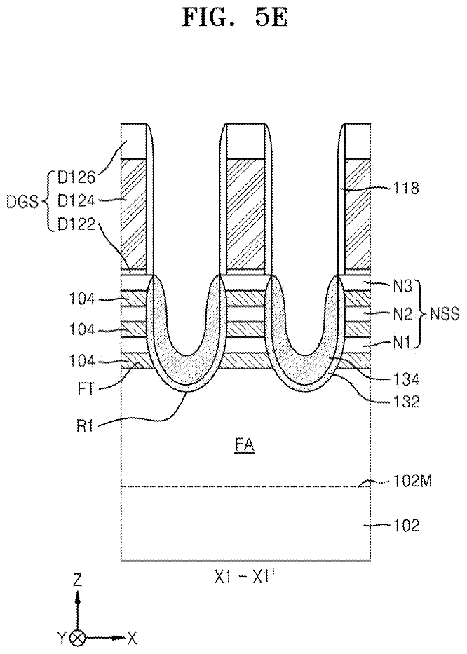

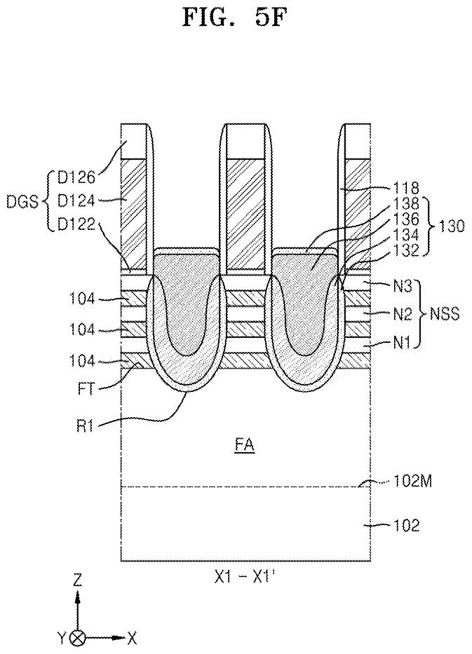

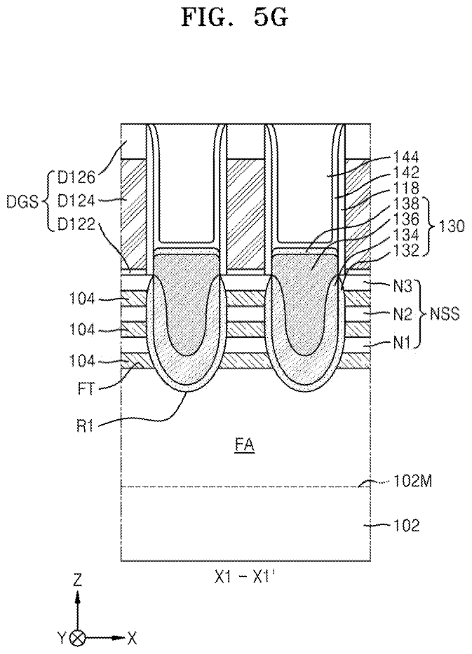

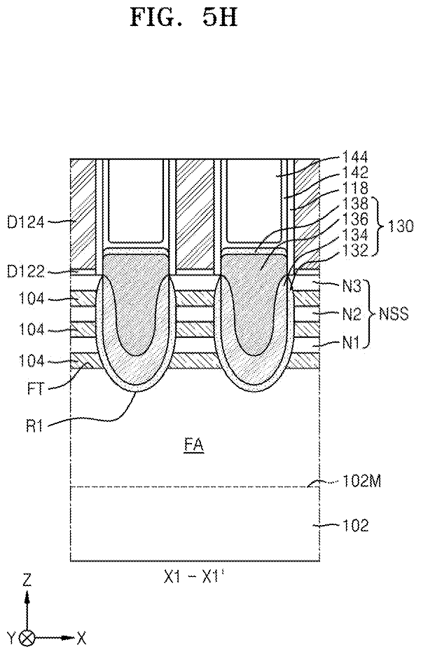

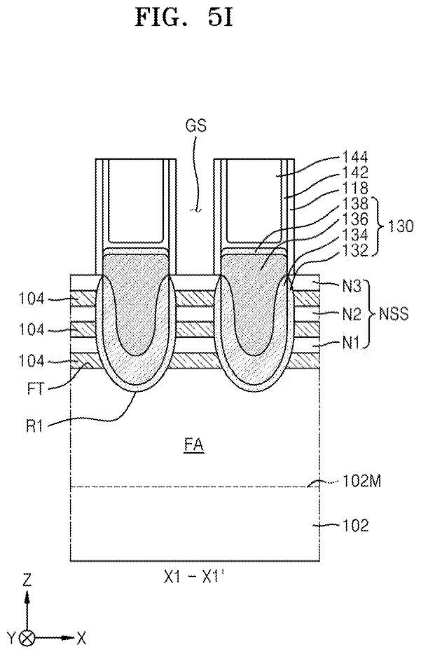

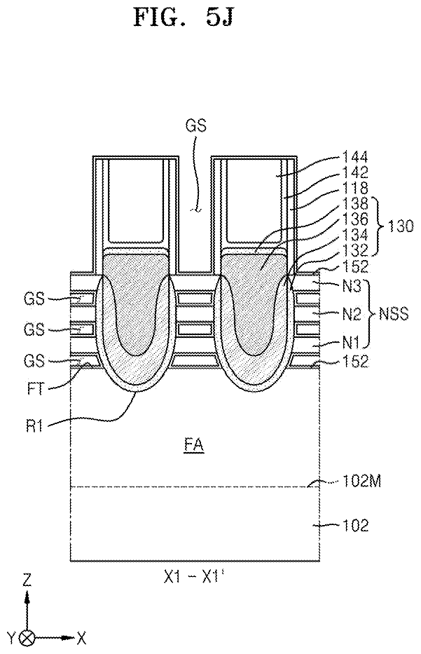

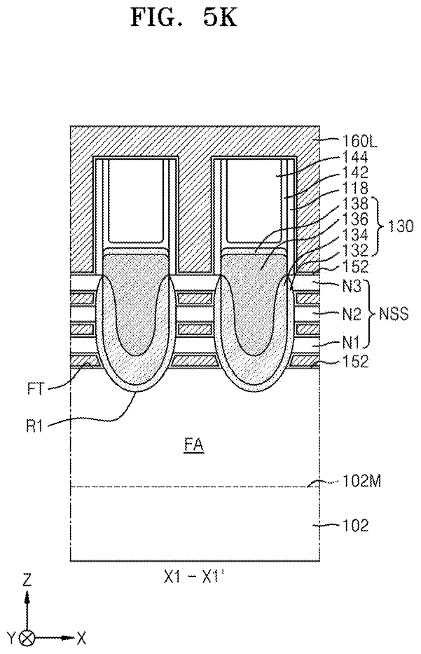

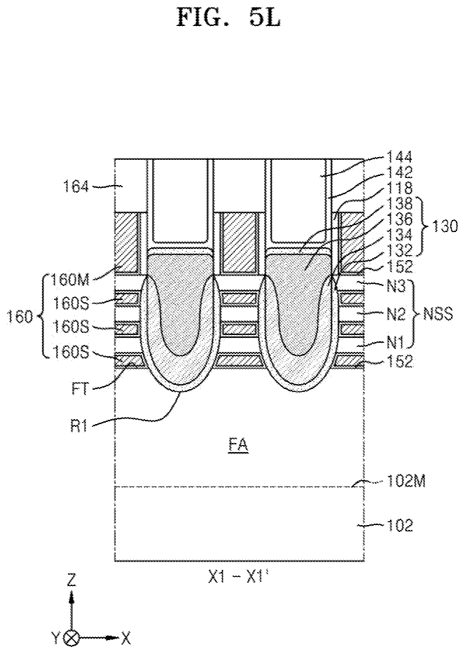

Referring to FIG. 4, the IC device 100 may include a plurality of fin-type active regions FA and a plurality of nanosheet stacks NSS. The plurality of fin-type active regions FA may protrude upward from a substrate (refer to 102 in FIG. 5A) in a vertical direction (Z direction) and extend long in a first lateral direction (X direction). The plurality of nanosheet stacks NSS may be on the plurality of fin-type active regions FA. As used herein, the term “nanosheet” refers to a conductive structure having a cross-section that is substantially perpendicular to a direction in which current flows. The nanosheet may be interpreted as including a nanowire.

A device isolation film 114 may be on the substrate 102 to cover both sidewalls of each of the plurality of fin-type active regions FA. The device isolation film 114 may include an oxide film, or a nitride film.

A plurality of gate lines 160 may be on the plurality of fin-type active regions FA. Each of the plurality of gate lines 160 may extend long in a second lateral direction (Y direction), which intersects with the first lateral direction (X direction)

A plurality of source/drain regions 130 may be respectively in upper portions of the plurality of fin-type active regions FA. Each of the plurality of source/drain regions 130 may be adjacent to at least one gate line 160 selected from the plurality of gate lines 160. Each of the plurality of source/drain regions 130 may have a sidewall in contact with at least one nanosheet included in the nanosheet stack NSS adjacent thereto.

FIGS. 5A to 5L are cross-sectional views of stages in a method for manufacturing an integrated circuit device according to example embodiments. An example method of manufacturing the IC device 100 shown in FIG. 4, according to an embodiment is described with reference to FIGS. 5A to 5L. FIGS. 5A to 5L each illustrate a cross-sectional configuration of a portion corresponding to a cross-section taken along line X1-X1′ of FIG. 4, according to a process sequence.

Referring to FIG. 5A, a plurality of sacrificial semiconductor layers 104 and a plurality of nanosheet semiconductor layers NS may be alternately stacked one-by-one on the substrate 102. Thereafter, portions of the plurality of sacrificial semiconductor layers 104, the plurality of nanosheet semiconductor layers NS, and the substrate 102 may be etched to define a plurality of fin-type active regions FA in the substrate 102. Each of the plurality of fin-type active regions FA may be formed to protrude upward from the substrate 102 in a vertical direction (Z direction) and extend long in a first lateral direction (X direction). A stack structure of the plurality of sacrificial semiconductor layers 104 and the plurality of nanosheet semiconductor layers NS may remain on a fin top surface FT of each of the plurality of fin-type active regions FA. Thereafter, a device isolation film (refer to 114 in FIG. 4) may be formed to cover both sidewalls of each of the plurality of fin-type active regions FA.

The substrate 102 may include a semiconductor, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms “SiGe,” “SiC,” “GaAs,” “InAs,” “InGaAs,” and “InP” refers to a material including elements included therein, without referring to a chemical formula representing a stoichiometric relationship.

The plurality of sacrificial semiconductor layers 104 and the plurality of nanosheet semiconductor layers NS may include semiconductor materials having different etch selectivities. In embodiments, the plurality of nanosheet semiconductor layers NS may include a silicon (Si) layer, and the plurality of sacrificial semiconductor layers 104 may include a silicon germanium (SiGe) layer. In embodiments, the plurality of sacrificial semiconductor layers 104 may have a constant Ge content. The SiGe layer included in the plurality of sacrificial semiconductor layers 104 may have a constant Ge content, which is selected in a range of about 5 at % to about 60 at %, e.g., about 10 at % to about 40 at %. The Ge content of the SiGe layer included in the plurality of sacrificial semiconductor layers 104 may be variously selected as needed.

Referring to FIG. 5B, a plurality of dummy gate structures DGS may be formed on the stack structure of the plurality of sacrificial semiconductor layers 104 and the plurality of nanosheet semiconductor layers NS.

Each of the plurality of dummy gate structures DGS may be formed to extend long in the second lateral direction (Y direction). Each of the plurality of dummy gate structures DGS may have a structure in which an oxide film D122, a dummy gate layer D124, and an insulating capping layer D126 are sequentially stacked. In embodiments, the dummy gate layer D124 may include polysilicon, and the insulating capping layer D126 may include a silicon nitride film.

Referring to FIG. 5C, a plurality of insulating spacers 118 may be formed to cover both sidewalls of each of the plurality of dummy gate structures DGS. The plurality of insulating spacers 118 may include SiN, SiON, SiOCN, SiBN, or SiCN.

Thereafter, a portion of each of the plurality of sacrificial semiconductor layers 104 and the plurality of nanosheet semiconductor layers NS and a portion of the fin-type active region FA may be etched by using the plurality of dummy gate structures DGS and the plurality of insulating spacers 118 as etch masks. Thus, the plurality of nanosheet semiconductor layers NS may be divided into a plurality of nanosheet stacks NSS, and a plurality of recesses R1 may be formed in an upper portion of the fin-type active region FA. Each of the plurality of nanosheet stacks NSS may include a first nanosheet N1, a second nanosheet N2, and a third nanosheet N3 To form the plurality of recesses R1, an etching process may be performed by using a dry etching process, or a wet etching process.

Referring to FIG. 5D, a first buffer layer 132 may be formed on the fin-type active region FA on both sides of each of the plurality of nanosheet stacks NSS. In embodiments, to form the first buffer layer 132, a semiconductor material may be epitaxially grown from a surface of the fin-type active region FA, which is exposed at a bottom surface of the recess R1, a sidewall of each of the first to third nanosheets N1, N2, and N3 included in the nanosheet stack NSS, and a sidewall of each of the plurality of sacrificial semiconductor layers 104. The first buffer layer 132 may be formed to contact each of the first to third nanosheets N1, N2, and N3 included in the nanosheet stack NSS in the first lateral direction (X direction) and contact the fin-type active region FA.

To form the first buffer layer 132, an LPCVD process, an SEG process, or a CDE process may be performed by using source materials including an elemental semiconductor precursor. The elemental semiconductor precursor may include a Si source or a Ge source.

In embodiments, the first buffer layer 132 may be formed by using the process described with reference to FIGS. 1, 2A, and 2B. In an implementation, to form the first buffer layer 132, a disilane compound including at least two Cl atoms, a Ge element-containing gas, and hydrogen (H₂) gas may be simultaneously supplied onto the substrate 102, and a SiGe layer may be epitaxially grown from the surface of the fin-type active region FA, which is exposed at the bottom surface of the recess R1, the sidewall of each of the first to third nanosheets N1, N2, and N3 included in the nanosheet stack NSS, and the sidewall of each of the plurality of sacrificial semiconductor layers 104. The formation of the first buffer layer 132 may be performed at a relatively low temperature of about 300° ° C. to about 500° ° C., e.g., about 350° C. to about 450° C.

In embodiments, when the first buffer layer 132 is formed, the disilane compound included in the process gas may include PCDS, and the Ge element-containing gas included in the process gas may include germane (GeH₄). In the process of the first buffer layer 132, an additional Cl element-containing gas (e.g., HCl) may not be used in addition to the disilane compound.

In embodiments, to form the first buffer layer 132, a flow rate of each of the disilane compound and the Ge element-containing gas, which are simultaneously supplied onto the substrate 102, may be determined such that a ratio of a content of germanium atoms to a content of silicon atoms in the process gas is at least 20%, e.g., at least 30%. Accordingly, a deposition selectivity may be further improved during the formation of the first buffer layer 132. Thus, the SiGe layer may be inhibited from being formed on a surface of each of the insulating spacer 118 and the insulating capping layer D126, which are exposed near the plurality of recesses R1, without using an additional etch gas (e.g., HCl), while the first buffer layer 132 is selectively formed in regions of the plurality of recesses R1 at which a semiconductor film is exposed.

When the first buffer layer 132 includes a SiGe layer doped with boron (B) atoms, the process gas may further include a boron precursor. Diborane (B2H6), triborane, tetraborane, or pentaborane may be used as the boron precursor.

Referring to FIG. 5E, a second buffer layer 134 may be formed on the first buffer layer 132 in the resultant structure of FIG. 5D. In a cross-section taken in the first lateral direction (X direction), a thickness of the second buffer layer 134 may be greater than a thickness of the first buffer layer 132 in the vertical direction (Z direction) from a lowermost surface of a source/drain region 130 on the fin-type active region FA.

In embodiments, to form the second buffer layer 134, a process similar to the process of forming the first buffer layer 132, which has been described with reference to FIG. 5D, may be performed. However, in the process of forming the second buffer layer 134, a ratio of a flow rate of the Ge element-containing gas to a flow rate of the disilane compound in the process gas may be higher than in the process of forming the first buffer layer 132. In an implementation, in the process of forming the second buffer layer 134, a ratio of a flow rate of germane (GeH₄) gas to a flow rate of PCDS in the process gas may be higher than in the process of forming the first buffer layer 132.

Referring to FIG. 5F, in the resultant structure of FIG. 5E, a main body layer 136 and a capping layer 138 may be sequentially formed on the second buffer layer 134, thereby forming the source/drain region 130.

To form the main body layer 136, processes similar to the process of forming the first buffer layer 132, which has been described with reference to FIG. 5D, or the process of forming the second buffer layer 134, which has been described with reference to FIG. 5E, may be performed. To form the main body layer 136, the flow rate of each of the disilane compound and the Ge element-containing gas, which are simultaneously supplied onto the substrate 102, may be determined such that a ratio of a content of germanium atoms to a content of silicon atoms in the process gas is at least 20%, e.g., at least 30%. However, in the process of forming the main body layer 136, a ratio of the flow rate of the Ge element-containing gas to the flow rate of the disilane compound in the process gas may be higher than in the process of forming the second buffer layer 134. In an implementation, in the process of forming the main body layer 136, a ratio of the flow rate of germane (GeH₄) gas to the flow rate of PCDS in the process gas may be higher than in the process of forming the second buffer layer 134. As a result, a deposition selectivity may be further improved during the formation of the main body layer 136. Thus, a SiGe layer may be inhibited from being formed on the surface of each of the insulating spacer 118 and the insulating capping layer D126, which are exposed near the plurality of recesses R1, without using an additional etch gas (e.g., HCl), while the main body layer 136 may be selectively formed only in the regions of the plurality of recesses R1 at which the semiconductor film is exposed.

In a plurality of source/drain regions 130, the first buffer layer 132, the second buffer layer 134, and the main body layer 136 may each include a Si₁₋ₓGeₓ layer (0<x<1) doped with a p-type dopant and have different Ge content ratios from each other. In embodiments, each of the first buffer layer 132, the second buffer layer 134, and the main body layer 136 may include a Si₁₋ₓGeₓ layer (0<x<1) doped with a p-type dopant, and a Ge content ratio of the second buffer layer 134 may be higher than a Ge content ratio of the first buffer layer 132 and lower than a Ge content ratio of the main body layer 136. In an implementation, each of the first buffer layer 132, the second buffer layer 134, and the main body layer 136 may include a Si₁₋ₓGeₓ layer (0<x<1) doped with a B element. Each of the first buffer layer 132, the second buffer layer 134, and the main body layer 136 may have a Ge content ratio and a B element concentration, which gradually increase in a direction away from the fin-type active region FA in the vertical direction (Z direction).

The capping layer 138 may include an undoped Si layer, a Si layer doped with a p-type dopant, or a SiGe layer having a lower Ge content ratio than the main body layer 136. In embodiments, the capping layer 138 may not include a Ge element. In an implementation, the capping layer 138 may include an undoped Si layer. In other embodiments, the capping layer 138 may include a Si layer doped with a B element or a SiGe layer doped with the B element. In still other embodiments, the capping layer 138 may be omitted.

In embodiments, the first buffer layer 132 may include a Si₁₋ₓGeₓ layer (0.05≤ x≤ 0.07) doped with the B element, the second buffer layer 134 may include a Si₁₋ₓGeₓ layer (0.40≤ x<0.45) doped with the B element, and the main body layer 136 may include a Si₁₋ₓGeₓ layer (0.45<x≤ 0.70) doped with the B element. In an implementation, a Ge content ratio of the second buffer layer 134 may be in a range of about 40 at % to about 45 at %, and a Ge content ratio of the main body layer 136 may be more than about 45 at % and equal to or lower than about 60 at %.

In embodiments, a concentration of the p-type dopant in the second buffer layer 134 may be higher than a concentration of the p-type dopant in the first buffer layer 132 and lower than a concentration of the p-type dopant in the main body layer 136. In embodiments, in each of the first buffer layer 132, the second buffer layer 134, and the main body layer 136, the p-type dopant may include a boron (B) element, a concentration of the B element in the second buffer layer 134 may be higher than a concentration of the B element in the first buffer layer 132 and lower than a concentration of the B element in the main body layer 136. In an implementation, a B element concentration of the first buffer layer 132 may be about 2E18 atoms/cm³ or more and about 7E18 atoms/cm³ or less, a B element concentration of the second buffer layer 134 may be about 1E20 atoms/cm³ and less than about 5E20 atoms/cm³, and a B element concentration of the main body layer 136 may be about 5E20 atoms/cm³ or more and about 7E20 atoms/cm³ or less.

According to the process of forming the plurality of source/drain regions 130, which has been described above with reference to FIGS. 5D to 5F, the SiGe layer may be deposited at a relatively low temperature of about 300° C. to about 500° C., e.g., about 350° C. to about 450° C., and a deposition rate of the SiGe layer may be relatively high. In addition, by improving a deposition selectivity, a SiGe layer may be inhibited from being formed on the surface of each of the insulating spacer 118 and the insulating capping layer D126, which are exposed near the plurality of recesses R1, without using an additional etch gas (e.g., HCl), while the plurality of source/drain regions 130 may be selectively formed in the regions of the plurality of recesses R1 at which the semiconductor film is exposed.

Referring to FIG. 5G, an insulating liner 142 may be formed to cover the resultant structure of FIG. 5F in which the plurality of source/drain regions 130 are formed, and an inter-gate dielectric film 144 may be formed on the insulating liner 142. Thereafter, the insulating liner 142 and the inter-gate dielectric film 144 may be planarized to expose a top surface of the insulating capping layer D126.

The insulating liner 142 may include silicon nitride (SiN), silicon oxide (SiO), SiCN, SiBN, SION, SiOCN, SiBCN, or SiOC. The inter-gate dielectric film 144 may include a silicon nitride film, a silicon oxide film, SiON, or SiOCN.

Referring to FIG. 5H, a top surface of the dummy gate layer D124 may be exposed by removing the insulating capping layer D126 from the resultant structure of FIG. 5G, and the insulating liner 142 and the inter-gate dielectric film 144 may be partially removed such that a top surface of the inter-gate dielectric film 144 and the top surface of the dummy gate layer D124 substantially end up at the same level as each other.

Referring to FIG. 5I, a gate space GS may be prepared by removing the dummy gate layer D124 and the oxide film D122 located thereunder from the resultant structure of FIG. 5H, and the plurality of nanosheet stacks NSS may be exposed through the gate space GS.

Referring to FIG. 5J, in the resultant structure of FIG. 5I, the plurality of sacrificial semiconductor layers 104 remaining on the fin-type active region FA may be removed through the gate space GS, and thus, the gate space GS may extend to respective spaces between the first to third nanosheets N1, N2, and N3 and a space between the first nanosheet N1 and the fin top surface FT of the fin-type active region FA.

In embodiments, to selectively remove the plurality of sacrificial semiconductor layers 104, differences in etch selectivity between the first to third nanosheets N1, N2, and N3 and the plurality of sacrificial semiconductor layers 104 may be used. A liquid or gaseous etchant may be used to selectively remove the plurality of sacrificial semiconductor layers 104. In embodiments, to selectively remove the plurality of sacrificial semiconductor layers 104, a CH₃COOH-based etchant, e.g., an etchant including a mixture of CH₃COOH, HNO₃, and HF or an etchant including a mixture of CH₃COOH, H₂O₂, and HF may be used.

Afterwards, a gate dielectric film 152 may be formed to cover respective exposed surfaces of the first to third nanosheets N1, N2, and N3 and the fin-type active region FA. In embodiments, the gate dielectric film 152 may have a stack structure of an interface dielectric film and a high-k dielectric film. The interface dielectric film may include a low-k dielectric material film (e.g., a silicon oxide film, or a silicon oxynitride film), which has a dielectric constant of about 9 or less. In embodiments, the interface dielectric film may be omitted. The high-k dielectric film may include a material having a higher dielectric constant than a silicon oxide film. In an implementation, the high-k dielectric film may have a dielectric constant of about 10 to about 25. The high-k dielectric film may include hafnium oxide. The gate dielectric film 152 may be formed by using an atomic layer deposition (ALD) process.

Referring to FIG. 5K, in the resultant structure of FIG. 5J, a gate-forming conductive layer 160L may be formed to cover the top surface of the inter-gate dielectric film 144 while filling the gate space (refer to GS in FIG. 5J) on the gate dielectric film 152.

The gate-forming conductive layer 160L may include a metal, a metal nitride, or a metal carbide. The metal may be titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). The metal nitride may be titanium nitride (TiN) or tantalum nitride (TaN). The metal carbide may include titanium aluminum carbide (TiAlC). The gate-forming conductive layer 160L may be formed using an ALD process or a CVD process.

Referring to FIG. 5L, in the resultant structure of FIG. 5K, the gate-forming conductive layer 160L and the gate dielectric film 152 may be partially removed from top surfaces thereof to expose the top surface of the inter-gate dielectric film 144 and empty an upper portion of the gate space GS again to form a gate line 160. In this case, the plurality of insulating spacers 118 may also be partially consumed from upper portions thereof, and thus, a height of each of the plurality of insulating spacers 118 may be lowered. Thereafter, a capping insulating pattern 164 filling the gate space GS may be formed on the gate line 160. The capping insulating pattern 164 may include a silicon nitride film.

By way of summation and review, a method of manufacturing an IC device is disclosed, which may include a process of selectively forming a silicon-containing layer only on a specific film on a surface at which different films are exposed. Accordingly, a technique may exist including selectively forming a silicon-containing layer only on some films including specific materials on a surface at which a plurality of films including different materials are exposed, in a process of manufacturing an IC device. A method of manufacturing an integrated circuit (IC) device is disclosed, which may improve manufacturing efficiency and reliability by selectively forming a silicon-containing layer only on a semiconductor film, from among the semiconductor film and an insulating film, on a surface at which a plurality of films including different materials are exposed, during a process of manufacturing the IC device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made.

What is claimed is:

1. A method of manufacturing an integrated circuit device, the method comprising:
forming a structure on a substrate, a semiconductor film and an insulating film being exposed in the structure; and
selectively forming a silicon germanium layer only on the semiconductor film by using a process gas, the process gas including a germanium element-containing gas, hydrogen gas, and a disilane compound having at least two chlorine atoms.

2. The method as claimed in claim 1, wherein the disilane compound includes dichlorodisilane, trichlorodisilane, tetrachlorodisilane, pentachlorodisilane, or hexachlorodisilane.

3. The method as claimed in claim 1, wherein the forming of the silicon germanium layer is performed at a temperature of about 350° C. to about 450° C.

4. The method as claimed in claim 1, wherein the germanium element-containing gas includes germane or digermane.

5. The method as claimed in claim 1, wherein, in the forming of the silicon germanium layer, an additional chlorine element-containing gas is not used in addition to the disilane compound.

6. The method as claimed in claim 1, wherein:
the insulating film includes a nitrogen-containing insulating film, and
the semiconductor film includes a silicon film or a silicon germanium layer.

7. The method as claimed in claim 1, wherein:
the process gas further includes at least one dopant precursor, and
the at least one dopant precursor includes a boron precursor or a gallium precursor.

8. The method as claimed in claim 1, wherein the process gas includes pentachlorodisilane, germane, hydrogen gas, and a boron dopant precursor.

9. The method as claimed in claim 1, wherein the forming of the silicon germanium layer includes simultaneously supplying the disilane compound, the germanium element-containing gas, and the hydrogen gas onto the substrate.

10. The method as claimed in claim 1, wherein, in the forming of the silicon germanium layer, a ratio of a content of germanium atoms to a content of silicon atoms in the process gas is at least 30%.

11. A method of manufacturing an integrated circuit device, the method comprising:
forming a fin-type active region on a substrate, the fin-type active region extending long in a first lateral direction;
forming a plurality of dummy gate structures on the fin-type active region, the plurality of dummy gate structures extending long in a second lateral direction, and each dummy gate structure including a dummy gate layer and an insulating capping layer covering the dummy gate layer, wherein the second lateral direction intersects with the first lateral direction;
forming a plurality of insulating spacers covering both sidewalls of each of the plurality of dummy gate structures;
etching a portion of the fin-type active region by using the plurality of dummy gate structures and the plurality of insulating spacers as an etch mask to form a recess in the fin-type active region; and
selectively forming a source/drain region on a surface of the fin-type active region, which is exposed at the recess, by using a process gas, the process gas including a germanium element-containing gas, hydrogen gas, and a disilane compound having at least two chlorine atoms.

12. The method as claimed in claim 11, wherein:
in the forming of the source/drain region, the disilane compound includes dichlorodisilane, trichlorodisilane, tetrachlorodisilane, pentachlorodisilane, or hexachlorodisilane, and
the germanium element-containing gas includes germane or digermane.

13. The method as claimed in claim 11, wherein the forming of the source/drain region is performed at a temperature of about 350° C. to about 450° C.

14. The method as claimed in claim 11, wherein, in the forming of the source/drain region, the process gas further includes a boron precursor.

15. The method as claimed in claim 11, wherein:
in the forming of the source/drain region, the process gas includes pentachlorodisilane, germane and hydrogen gas, and
the forming of the source/drain region includes simultaneously supplying the pentachlorodisilane, the germane, and the hydrogen gas onto the substrate.

16. The method as claimed in claim 11, wherein:
the forming of the source/drain region includes forming a first buffer layer, a second buffer layer, and a main body layer, which are sequentially stacked in a direction away from the fin-type active region,
the first buffer layer, the second buffer layer, and the main body layer each include a Si₁₋ₓGeₓ layer, in which 0<x<1, doped with a p-type dopant and have different germanium content ratios from each other, and
a ratio of a flow rate of the germanium element-containing gas to a flow rate of the disilane compound in the process gas during the forming of the main body layer is higher than a ratio of the flow rate of the germanium element-containing gas to the flow rate of the disilane compound in the process gas during the forming of the second buffer layer.

17. The method as claimed in claim 11, wherein:
the forming of the source/drain region includes simultaneously supplying the disilane compound, the germanium element-containing gas, and the hydrogen gas onto the substrate, and
a flow rate of each of the disilane compound and the germanium element-containing gas, which are simultaneously supplied onto the substrate, is determined such that a ratio of a content of germanium atoms to a content of silicon atoms in the process gas is at least 30%.

18. The method as claimed in claim 11, wherein:
the fin-type active region includes a silicon film,
each of the insulating capping layer and the insulating spacer includes a nitrogen-containing insulating film,
the source/drain region includes a Si₁₋ₓGeₓ layer, in which 0<x<1, doped with a p-type dopant, and
the source/drain region has a higher germanium content ratio in a direction away from the fin-type active region in a vertical direction from a bottom surface of the recess.

19. A method of manufacturing an integrated circuit device, the method comprising:
forming a fin-type active region on a substrate, the fin-type active region extending long in a first lateral direction;
forming a plurality of dummy gate structures on the fin-type active region, the plurality of dummy gate structures extending long in a second lateral direction, and each dummy gate structure including a dummy gate layer and an insulating capping layer covering the dummy gate layer, wherein the second lateral direction intersects with the first lateral direction;
forming a plurality of insulating spacers covering both sidewalls of each of the plurality of dummy gate structures;
forming a nanosheet stack apart from a fin top surface of the fin-type active region, the nanosheet stack facing the fin top surface of the fin-type active region in a vertical direction, and the nanosheet stack including a plurality of nanosheets that are at different vertical distances from the fin top surface of the fin-type active region;
etching a portion of the fin-type active region by using the plurality of dummy gate structures and the plurality of insulating spacers as an etch mask to form a recess in the fin-type active region; and
epitaxially growing a silicon germanium layer from a surface of the fin-type active region and a surface of each of the plurality of nanosheets at a temperature of about 350° C. to about 450° C. by using a process gas to form a source/drain region, the process gas including a disilane compound having at least two chlorine atoms, a germanium element-containing gas, and hydrogen gas.

20. The method as claimed in claim 19, wherein:
in the forming of the source/drain region, the process gas includes pentachlorodisilane, germane, hydrogen gas, and a boron dopant precursor, and at least the pentachlorodisilane, the germane, and the hydrogen gas of the process gas are simultaneously supplied onto the substrate, and
a flow rate of each of the disilane compound and the germanium element-containing gas, which are simultaneously supplied onto the substrate, is determined such that a ratio of a content of germanium atoms to a content of silicon atoms in the process gas is at least 30%.
